(19) United States
(12) Patent Application Publication
(10) Pub. No.: US 2024/0348221 A1
(43) Pub. Date: Oct. 17, 2024

(54) PERSONAL STAGE MONITORING SYSTEM WITH PERSONAL MIXING

(71) Applicant: Shure Acquisition Holdings, Inc., Niles, IL (US)

(72) Inventor: Bryan Lee Jozwiak, Bartlett, IL (US)

(21) Appl. No.: 18/631,230

(22) Filed: Apr. 10, 2024

Related U.S. Application Data
(60) Provisional application No. 63/495,621, filed on Apr. 12, 2023.

(51) Int. Cl. H03G 1/02; G10H 1/00; H03G 9/00

(52) U.S. Cl. CPC H03G 1/02; G10H 1/0008; H03G 9/005

(57) ABSTRACT

Aspects of the disclosure relate to personal stage monitoring (PSM) systems and methods. A PSM system may include a transmitter and a receiver, where the transmitter may transmit audio data to the receiver to provide performers with monitoring feedback. The PSM transmitter may include audio processing and/or personal mixing devices that provide a customized mix of audio signals that may be transmitted to the receiver. The integration of the audio processing and/or mixing devices with the PSM transmitter advantageously reduces the complexity of the overall audio system and improves audio quality and performance by reducing noise and latency of the audio system.

### CROSS REFERENCE TO RELATED APPLICATIONS

This patent application claims priority to, and the benefit of, U.S. Provisional Patent Application No. 63/495,621, filed Apr. 12, 2023, which is incorporated herein by reference in its entirety.

### TECHNICAL FIELD

Aspects of the disclosure relate to personal stage monitoring (PSM) systems and more specifically to PSM systems including personal mixing and/or other audio processing configurations.

### BACKGROUND

Live performance environments, such as music concerts, theatrical productions, and other events, require enabling performers to hear themselves and other performers clearly in order to deliver their best performance.

An audio system may include a PSM system to provide performers with monitoring feedback using, for example, monitoring speakers on stage or in-ear monitors (IEMs). Feedback to the performers allows performers to hear themselves and other performers more clearly, even in noisy environments. To process the audio feedback, the audio system may further include audio processing and mixing devices that supply the PSM system with processed audio signals that are then provided to the respective performer using the PSM system. Such multi-device systems often require several wired connections (e.g., cables, connectors, etc.). Further, the control of the multiple devices requires multiple interfaces, cables, and control devices. The use of multiple devices, cables, and associated control interfaces may also impact quality and cause latency issues, in addition to increased complexity and costs.

### SUMMARY

Aspects of the disclosure provide effective, scalable, and reliable technical solutions that address and overcome the problems associated with operation of complex audio systems including PSM systems.

An example audio system may include a chain of discrete subcomponents, each configured to perform a specific audio processing functionality. For example, the subcomponents may include microphones, receivers, mixers, amplifiers, speakers, a PSM system, musical instruments, general-purpose computing devices, etc.

A PSM system may include a transmitter and a receiver, where the transmitter may transmit audio data to the receiver to provide performers with monitoring feedback. The receiver may be one or more monitoring speakers on stage, or a portable device worn by the performer that may include an audio output, such as in-ear monitors (IEMs). Feedback to the performers may allow performers to hear themselves, instruments, audio tracks, and/or other performers more clearly, even in noisy environments. To tailor the feedback, the PSM transmitting device may include audio processing and/or mixing devices that provide a customized mix of audio signals that may be transmitted to the receiving device. Such a configuration may provide a PSM system with personal mixing for one or more performers. The integration of the audio processing and/or mixing devices with the PSM transmitting device advantageously reduces the complexity of the overall audio system by, for example, reducing the number of discrete components making up the audio system and/or reducing the necessary connections between devices. Further advantageous may include improved audio quality and performance by reducing noise (e.g. that may be introduced from wired and/or wireless connections) and/or reducing latency of the audio system.

### BRIEF DESCRIPTION OF THE DRAWINGS

The present disclosure is illustrated by way of example and not limited in the accompanying figures in which like reference numerals indicate similar elements and in which:

FIG. 1 shows a PSM system according to one or more exemplary embodiments.

FIG. 2 shows a PSM system according to one or more exemplary embodiments.

FIG. 3 shows an example operation of a PSM system according to one or more exemplary embodiments.

FIG. 4 shows a PSM system, according to one or more exemplary embodiments, including a PSM transmitter having a personal mixer.

FIG. 5 shows an example operation of a PSM system having an integrated personal mixer according to one or more exemplary embodiments.

FIG. 6 shows a PSM system including a user device according to one or more exemplary embodiments.

FIG. 7 shows a method of audio signal processing according to one or more exemplary embodiments.

### DETAILED DESCRIPTION

In the following description of various illustrative embodiments, reference is made to the accompanying drawings, which form a part hereof, and in which is shown, by way of illustration, various embodiments in which aspects of the disclosure may be practiced. It is to be understood that other embodiments may be utilized, and structural and functional modifications may be made, without departing from the scope of the present disclosure. It is noted that various connections between elements are discussed in the following description. It is noted that these connections are general and, unless specified otherwise, may be direct or indirect, wired or wireless, and that the specification is not intended to be limiting in this respect.

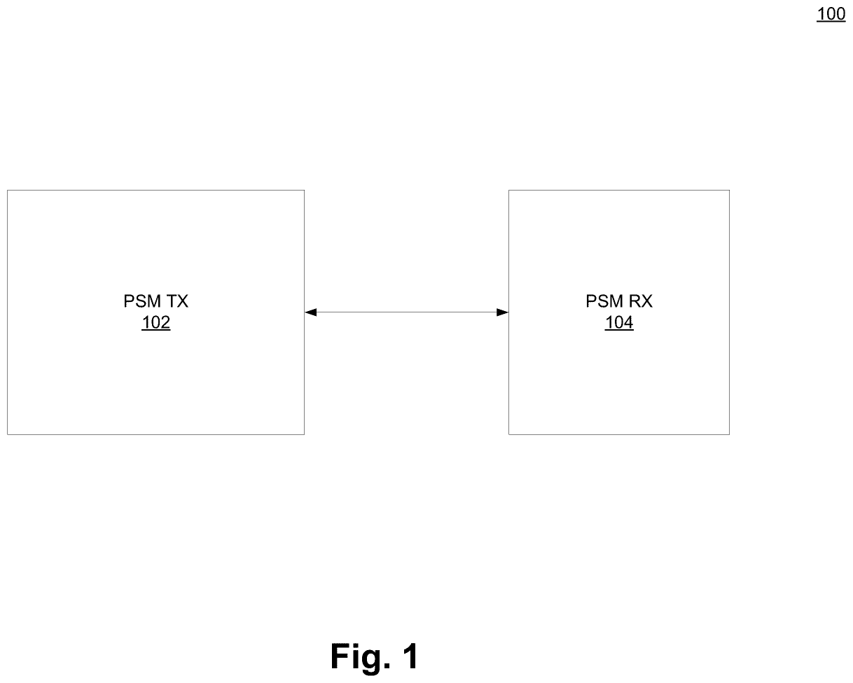

With reference to FIG. 1, a personal stage monitoring (PSM) system 100 according to one or more exemplary embodiments may include a PSM transmitter 102 and a PSM receiver 104. The PSM transmitter 102 and PSM receiver 104 may be configured to communicate with each other using one or more communication protocols. In one or more aspects, the PSM transmitter 102 and/or the PSM receiver 104 may be configured as a transceiver that is configured to both transmit and receive information. The communications between the PSM transmitter 102 and PSM receiver 104 may be via one or more wireless and/or wired communication protocols.

The PSM transmitter 102 may be located, for example, at a sound board or sound booth, and configured to transmit audio signals to the PSM receiver 104. The PSM receiver may be located, for example, on the stage and associated with a monitor speaker, and/or may be implemented as a portable device that may be worn by the performer on stage. For example, the PSM receiver 104 may be worn by the performer and may include a bodypack that is attached to the performer's belt or clothing and headphones (e.g. in-car monitors (IEMs) that fit snugly in the performer's ears). The headphones are responsible for delivering the audio signals directly to the performer's ears, allowing them to hear themselves, instruments, audio tracks, and/or other performers clearly on stage. In operation, the PSM transmitter 102 and PSM receiver 104 work together to provide a monitoring audio stream for the performer on stage. The sound engineer may provide audio signals from an external mixing console or sound booth to the PSM transmitter 102, which may then transmit the audio signals to the PSM receiver 104 worn by the performer.

The PSM transmitter 102 may be configured to transmit and/or receive signals using one or more communication protocols, such as, the Bluetooth protocol, an Institution of Electrical and Electronics Engineers (IEEE) 802.11 WIFI protocol, a 3rd Generation Partnership Project (3GPP) cellular protocol, a local area network (LAN) protocol, a hypertext transfer protocol (HTTP), FM radio, infrared, one or more optical protocols, fiber optics, industrial, scientific, and medical (ISM) bands defined by the International Telecommunication Union (ITU) Radio Regulations (e.g., a 2.4 GHz-2.5 GHz band, a 5.75 GHz-5.875 GHz band, a 24 GHz-24.25 GHZ band, and/or a 61 GHz-61.5 GHz band, etc.), a very high frequency (VHF) band (e.g., 30 MHZ-300 MHz band) and/or via (e.g., one or more channels within) an ultra-high frequency (UHF) band (e.g., 300 MH2-3 GHZ). The communication protocols that may be used are not limited to these example protocols.

The PSM system 100 may be implemented with one or more other audio subcomponents to form an audio system that includes a chain of discrete subcomponents, each configured to perform a specific audio processing functionality. For example, the subcomponents may include microphones, receivers, mixers, amplifiers, speakers, musical instruments, general-purpose computing devices, etc.

As an example, an audio system may receive audio from one or more microphones and/or instruments, and process the audio via a receiver, a mixer, and/or amplifier(s), prior to outputting the audio via one or more speakers. Various examples herein describe a PSM system, or an audio system comprising a PSM system, that may be connected to one or more other audio devices (e.g., microphones, speakers, musical instruments and/or instrument outputs, transmitters, receivers, transceivers, computing devices, etc.). The PSM system may be flexibly configured to receive audio input from one or more audio sources (e.g. microphone(s), instrument(s), and/or audio track(s)) and provide monitoring feedback to the performer.

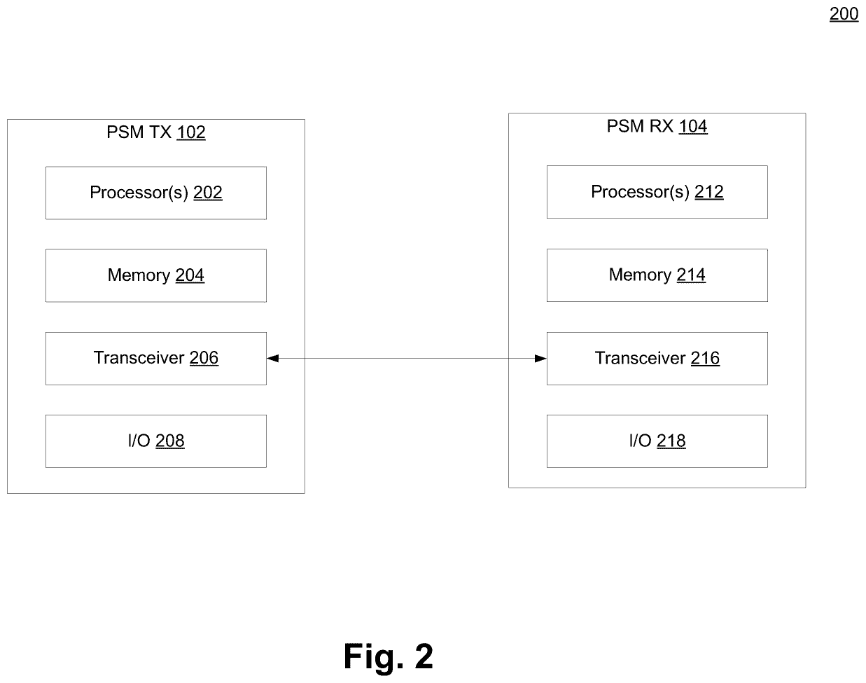

With reference to FIG. 2, according to one or more exemplary embodiments, the PSM transmitter 102 may include one or more of processor(s) 202, memory 204, transceiver(s) 206, and/or input/output (I/O) interface(s) 208. One or more data buses may interconnect the processor(s) 202, the memory 204, transceiver(s) 206, and/or I/O interface(s) 208. The PSM transmitter 102 may be implemented using one or more integrated circuits (ICs), software, or a combination thereof, configured to operate as described herein. The memory 204 may comprise any memory, such as a random-access memory (RAM), a read-only memory (ROM), a flash memory, or any other electronically readable memory, or the like. The memory 204 may include one or more memory units.

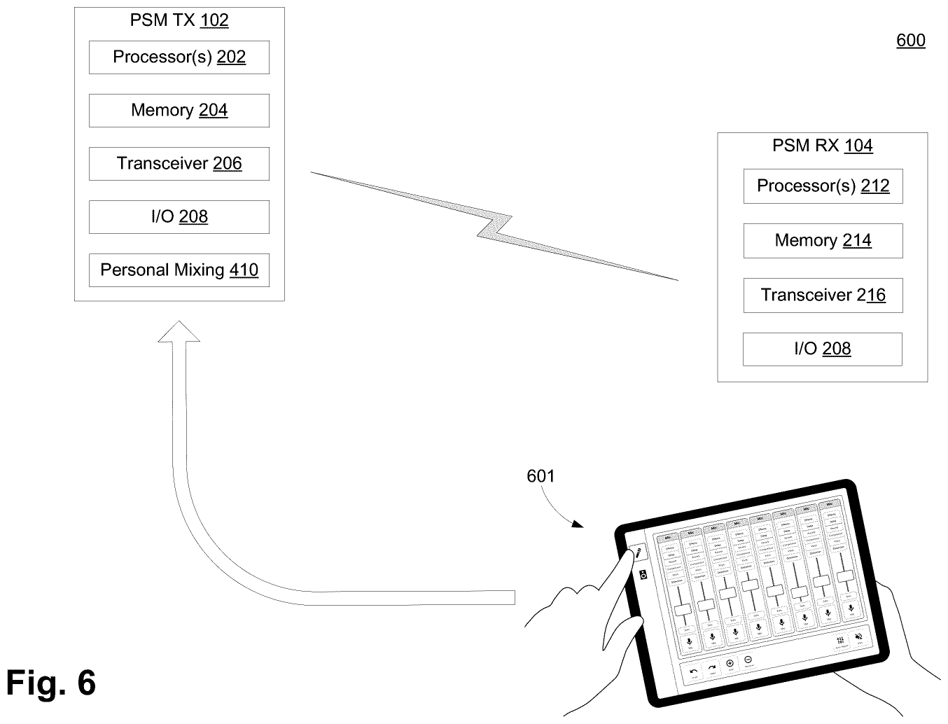

Signals transmitted from and/or received by the PSM transmitter 102 may be encoded in one or more data units. For example, the processor(s) 202 may be configured to generate data units, and process received data units, that conform to any suitable wired and/or wireless communication protocol. The processor(s) 202 may be configured to execute machine readable instructions stored in memory 204 to perform one or more operations described herein. The transceiver 206 may be configured to send/receive signals to/from PSM receiver 104 using one or more communication protocols. The communication protocols may be any wired communication protocol(s), wireless communication protocol(s), and/or one or more protocols corresponding to one or more layers in the Open Systems Interconnection (OSI) model (e.g., a LAN protocol, an IEEE 802.11 WIFI protocol, a 3GPP cellular protocol, an HTTP, a Bluetooth protocol, etc.). In one or more examples, and as further described herein with respect to FIG. 6, the PSM transmitter 102 may also communicate with one or more user devices 601 (e.g., smartphones, tablet computers, remote control devices, etc.) that may be configured to control operation of the PSM transmitter 102.

The I/O interface 208 may be configured to receive one or more inputs that allow the PSM transmitter 102 to receive audio signals from different sources, such as microphones, instruments, and playback devices. The audio signals may be received on one or more channels. The I/O interface 208 may include one or more input connections configured to receive input data and/or signals using one or more wired and/or wireless communication protocols, and/or may include one or more input devices (e.g. keyboard, control panel, graphical user interface (GUI), human-machine interface, or the like). Additionally, or alternatively, the I/O interface 208 may include one or more output connections configured to transmit output data and/or signals using one or more wired and/or wireless communication protocols, and/or may include one or more output devices (e.g. speaker, display, GUI, etc.). The I/O interface 208 may include a dedicated audio interface (e.g., 3.5 mm connector), a general-purpose interface (e.g., a universal serial bus (USB) connector), an XLR connector, or any other type of interface.

In an exemplary embodiment, the PSM receiver 104 may include one or more of processor(s) 212, memory 214, transceiver(s) 216, and/or I/O interface(s) 218. One or more data buses may interconnect the processor(s) 212, the memory 214, transceiver(s) 216, and/or I/O interface(s) 218. The PSM receiver 104 may be implemented using one or more ICs, software, or a combination thereof, configured to operate as described herein. The memory 214 may comprise any memory, such as RAM, ROM, a flash memory, or any other electronically readable memory, or the like. The memory 214 may include one or more memory units.

The PSM receiver 104 may receive one or more data units from the PSM transmitter 102 using the transceiver 216. The processor 212 may decode the data unit(s) received by the PSM receiver 104 to generate one or more audio signals. The processor(s) 212 may be configured to execute machine readable instructions stored in memory 214 to perform one or more operations described herein. The transceiver 216 may be configured to receive/send signals from/to the PSM transmitter 102 using one or more communication protocols (e.g., Bluetooth protocol, IEEE 802.11 WIFI protocol, 3GPP cellular protocol, LAN protocol, etc.). The audio signals generated by the PSM receiver 104 may be provided to the performer associated with the PSM receiver to provide the performer with monitoring feedback. This feedback allows performers to hear themselves, instruments, audio tracks, and/or other performers more clearly. The I/O interface 218 may be configured similarly as the I/O interface 208, and include one or more input connections configured to receive input data and/or signals using one or more wired and/or wireless communication protocols, and/or may include one or more input devices (e.g. keyboard, control panel, graphical user interface (GUI), human-machine interface, or the like). Additionally, or alternatively, the I/O interface 218 may include one or more output connections configured to transmit output data and/or signals using one or more wired and/or wireless communication protocols, and/or may include one or more output devices (e.g. speaker, display, GUI, etc.). The I/O interface 218 may include a dedicated audio interface (e.g., 3.5 mm connector), a general-purpose interface (e.g., a universal serial bus (USB) connector), an XLR connector, or any other type of interface.

Other devices in the audio system (e.g., mixers, amplifiers, speakers, musical instruments, general-purpose computing devices, etc.) may have an architecture similar to the PSM transmitter 102 and/or PSM receiver 104. For example, one or more of the other devices in the audio system may comprise corresponding memories, processors, transceivers, and/or I/O interfaces. In an exemplary embodiment, one or more components of the PSM transmitter 102 and/or the PSM receiver 104 may include processing circuitry (e.g. one or more processors and/or circuitry) that is configured to perform the respective functions and/or operations of the component(s).

Inputs to the PSM transmitter 102 (e.g. via the I/O interface 208) and/or to the PSM receiver 104 (e.g. via I/O interface 218) may be any audio, electrical, and/or electromagnetic signals (e.g., originated from any input devices and/or sources, such as from the performer(s), instrument(s), audio track(s), etc.) that may be processed by the PSM transmitter 102 and/or PSM receiver 104. Outputs from the PSM transmitter 102 and/or PSM receiver 104 may be any audio, electrical, and/or electromagnetic signals that may be played back via output devices, stored, and/or processed by other devices. Input devices that may provide input to the PSM transmitter 102 and/or PSM receiver 104 may comprise one or more of: wireless microphones, wearable packs (e.g., beltpacks) associated with microphones, wireless headsets integrated with a microphone, electronically-readable memory comprising stored audio, a computing device (e.g., smartphone, tablet) with integrated microphones, and/or a transceiver associated with a musical instrument. Output devices that may be connected to the PSM transmitter 102 and/or PSM receiver 104, and receive output from the PSM transmitter 102 and/or PSM receiver 104, may include one or more of: speakers, wearable packs (e.g., beltpacks) associated with headsets, a wireless headset, a user computing device, an electronically-readable memory, a transceiver associated with a musical instrument, an output interface (e.g., an XLR connector, USB connector, 3.5 mm connector, etc.), a server associated with a computing network (e.g., local network, public network such as the Internet), a computing device (e.g., smartphone, tablet) with integrated speakers or connected headphones, etc.

The PSM system 100 of FIG. 2 may be implemented with one or more other audio subcomponents to form an audio system. Such audio systems may include a complex configuration of interconnected discrete subcomponents, such as receivers, mixers, amplifiers, and the PSM system, resulting in a system having a large overall footprint. These audio systems may require careful consideration of compatibility between the devices and may result in added complexity (e.g. complex set-up, use, dismantle, and/or troubleshooting) due to the use of the multiple wired connections/adapters to connect the devices. In addition to the increased complexity, the various interconnections may introduce unwanted noise (e.g. switching noise and/or coupling) and/or latency, as well as being susceptible to equipment failures (e.g. cable breakage and disconnects).

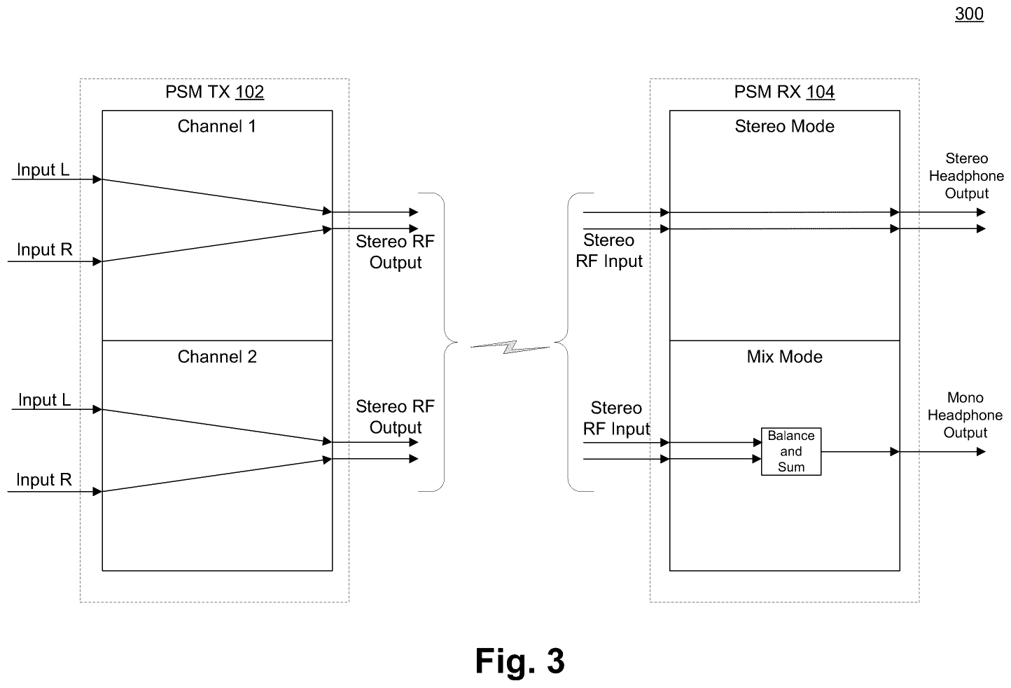

FIG. 3 illustrates an example operation 300 of audio system 200 according to one or more exemplary embodiments. The PSM transmitter 102 may receive one or more inputs on one or more channels. In the illustrated example, the PSM transmitter 102 is configured to accept inputs on two channels, but is not limited thereto. The first and/or second channels may be configured to receive a stereo audio signal that includes a left (L) audio input signal and a right (R) audio input signal. In other aspects, the inputs of the channels may include less (e.g. mono) or more audio input signals (e.g. surround). In an exemplary embodiment, the input signals are received by the PSM transmitter 102 via the I/O interface 208.

On the first and/or second channels, the stereo audio input signals are modulated to generate respective stereo radio-frequency (RF) output signals. For example, the transceiver 206 may modulate the stereo audio input signals onto a carrier wave to generate the RF output signals. The transceiver 206 may then transmit the RF output signals to the PSM receiver 104.

The PSM receiver 104 receives the RF output signals from the PSM transmitter 102. For example, the transceiver 216 of the PSM receiver 104 may down-convert the received RF signals to generate output monitor signals. In the illustrated example, the RF output signals on the first channel are converted to a stereo monitoring signal. On the second channel, the PSM receiver 104 may convert the stereo RF signal on the second channel to a mono monitoring signal. In this example, the PSM receiver 104 may balance and sum the two stereo audio input signals two generate the mono monitoring signal.

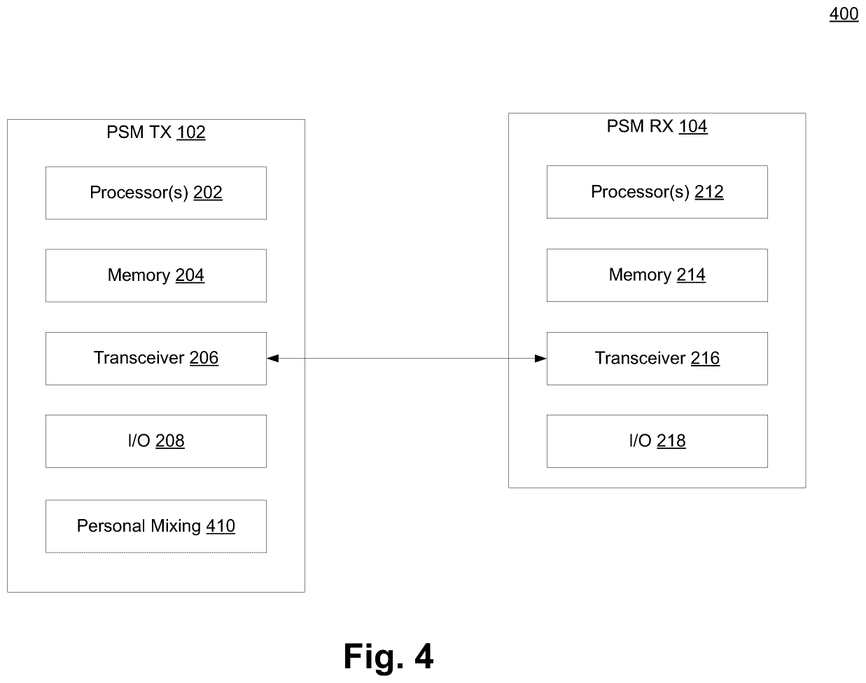

FIG. 4 illustrates an audio system 400 according to one or more exemplary embodiments in which the PSM transmitter 102 further includes one or more personal mixing device(s) 410. The personal mixing device 410 may be referred to as mixer 410. The mixer 410 may be configured to perform one or more audio mixing operations, digital signal processing (DSP), and/or other signal processing on the audio signals received (e.g. via I/O interface 208) to generate processed audio data. The processed audio data provides a customized mix of audio signals, which may then be transmitted to the PSM receiver 104 using the transceiver 206. Such a configuration may provide a PSM system with personal mixing for one or more performers. The mixing operations may be performed in the analog or digital domains. If multiple mixing operations are performed, one or more operations may be performed in the analog domain while one or more other operations may be performed in the digital domain. In an exemplary embodiment, the mixer 410 may include processing circuitry (e.g. one or more processors and/or circuitry) that is configured to perform the function and/or operations of the mixer 410.

In an exemplary embodiment, the mixer 410 may be configured to perform one or more mixing operations using machine learning (ML), such as using one or more ML models to adjust (e.g. optimize) mixing parameters to control the mixing operations of the mixer 410. The ML model may support a generative adversarial network, a bidirectional generative adversarial network, an adversarial autoencoder, or an equivalent thereof. Additionally, or alternatively, the ML model may be a convolutional neural network, a recurrent neural network, a recursive neural network, a long short-term memory (LSTM), a gated recurrent unit (GRU), an unsupervised pretrained network, a space invariant artificial neural network, or any equivalent thereof. The ML model may be trained based on input data and/or output data of the PSM transmitter 102 (e.g. mixer 410), PSM receiver 104, user device 601, one or more other components of the audio system, and/or one or more other devices in communication with the audio system. The ML model may be trained using different training techniques, such as supervised training, unsupervised training, semi-supervised training back propagation, transfer learning, stochastic gradient descent, learning rate decay, dropout, max pooling, batch normalization, and/or any equivalent deep learning technique. In one or more aspects, one or more other components of the PSM transmitter 102 and/or other component of the audio system may implement one or more ML models to perform their respective functions.

In one or more exemplary embodiments, the personal mixing operations may include the adjustment of audio levels, panning, equalization (EQ), dynamic EQ, compression, multiband compression, summing, filtering, noise reduction, reverb, gain, delay, gating, expansion, de-essing, ducking, saturation, harmonic distortion, one or more modulation effects, sidechaining, adjustments to one or more other audio parameters, and/or one or more other audio processing operations.

Panning may include the process of placing audio elements in the stereo field, so that they appear to come from a particular location in the audio spectrum. For example, by adjusting the left-right balance of a signal, panning may create a sense of space and dimensionality in a mix. Equalization (EQ) may include the process of adjusting the frequency balance of audio tracks to improve balance and/or clarity. Equalization may include cutting or boosting specific frequency ranges to remove unwanted frequencies or enhance desired ones, and/or may be used to achieve a desired tone or timbre. Dynamic EQ may include adjusting the gain of certain frequency bands based on the input level of the audio signal, and may be useful in controlling harsh frequencies or taming certain resonances. Compression may include the process of reducing the dynamic range of audio tracks, making loud sounds quieter and quiet sounds louder. By reducing the difference between the loudest and softest parts of a track, compression may provide a more consistent and controlled audio. Multiband Compression is similar to compression, but instead of applying a single level reduction to the entire audio signal, it applies different levels of compression to different frequency bands. Multiband compression may be used to balance out a mix that has a lot of frequency imbalances. Summing may include adding together two or more audio signals to create a single output signal. The summing of audio signals may preserve the relative volume levels and stereo placement. Filtering may include the process of removing or attenuating certain frequencies in an audio signal, and may be used to remove unwanted noise and/or resonances, and/or to shape the tone of an audio signal. Noise reduction may include removing unwanted noise from an audio signal, such as removing hiss, hum, and/or other types of noise that may degrade the audio quality. Reverb may include simulating an acoustic environment in which an audio signal was recorded, and may be used to add space, depth, and/or natural reverberation to an audio signal, and/or to create a sense of continuity between different parts of a mix. Gain may include adjusting the overall level of an audio signal, and may be used to balance levels of different audio tracks in a mix, and/or to increase or decrease the overall loudness of the audio track. Delay adjustments may include the introduction of a time delay between an audio signal and its output, and/or the introduction of echoes and/or repeats. Delay may be used to create stereo width and/or to create rhythmic effects. Gating may include the attenuating of an audio signal when it falls below a certain level, and may be used to remove unwanted noise and/or in controlling the decay of certain sounds. Expansion may be the opposite of compression, where instead of reducing the dynamic range of an audio signal, expansion increases it. Expansion may be used to increase the life and energy to a mix. De-essing may include the process of reducing the level of harsh sibilant sounds in an audio signal, such as “s” and “t” sounds. De-essing may make a mix sound less harsh and more pleasant to listen to. Ducking may include the reduction of the level of one audio signal when another audio signal is present. This can be useful in making a mix sound more cohesive and reducing clashes between different tracks. Saturation may include adding harmonic distortion to an audio signal, which may be used add warmth and character to a mix. Harmonic Distortion may include adding distortion to an audio signal to create new harmonic content. Modulation Effects may include effects (e.g. chorus, flanger, and phaser) that modulate certain aspects of an audio signal, such as pitch, frequency, and/or amplitude. Side chaining may include using the level of one or more audio signals to control the processing of one or more other audio signals. A side chain input may be used, for example, on a compressor or other processor, which allows the level of the separate audio signal(s) to control the amount of processing applied to the other audio signal(s). For example, in a music mix, a side chain input can be used to trigger a compressor on a bass track using the kick drum track as the side chain input. This may cause the bass to be compressed every time the kick drum hits, which can help to create a more cohesive and tight rhythm section. In another example, side chaining may be used in other applications, such as where a music track can be automatically ducked (e.g. reduced in volume) whenever the voiceover is present to ensure that the voiceover remains clear and audible over the music.

In one or more exemplary embodiments, the personal mixing operations may additionally or alternatively include one or more advanced processing algorithms, such as one or more audio processing that uses machine learning (ML) to adjust mixing parameters and/or control the mixing operations of the mixer 410. The advanced processing techniques may include spatialization, denoising, auto mixing, and/or one or more other advanced audio processing operations. Spatialization may create a sense of space and depth within an audio mix by, for example, placing different sounds in different locations within the stereo or surround sound field, creating a more immersive and realistic listening experience. Spatialization techniques may include panning, reverberation, and delay effects, as well as more advanced techniques like binaural and ambisonic processing. Denoising may include removing unwanted noise from an audio signal (e.g. drum bleed). Noise can come from a variety of sources, including background hum, hiss, or electronic interference. Denoising techniques may include spectral subtraction, noise gating, and/or adaptive filtering, as well as more advanced techniques like ML-based noise reduction algorithms. Denoising techniques may remove and/or attenuate unwanted noise while preserving the quality and clarity of the desired audio signal. Auto mixing may include one or more mixing operations that are at least partially automated (e.g. using ML). Auto mixing may include performing one or more audio processing operations to, for example, emphasize or deemphasize one or more channels.

The integration of the mixer 410 within the PSM transmitter 102 may allow the PSM transmitter 102 to tailor the feedback provided to the PSM receiver 104, while advantageously reducing the complexity and/or size of the overall audio system (e.g. by reducing the number of discrete components making up the audio system and reducing required intercommunions) and/or improving audio quality and performance by reducing noise (e.g. electrical switching noise and/or coupling) and/or latency of the audio system. Further, the integration provides the additional advantage of common temperature, process, and voltage conditions for the personal mixer 410, processor 202, and transceiver 206. These common conditions may allow for increased performance and efficiency in compensating the effects of these conditions on the performance of the personal mixer 410, processor 202, and transceiver 206.

Although one or more aspects are described with the PSM transmitter 102 including the mixer 410, the PSM receiver 104 may additionally or alternatively include a personal mixing device in one or more embodiments. For example, the PSM receiver 104 may include built-in limiters, EQ presets, and noise reduction, which can help to improve the overall sound quality and protect the performer's hearing.

In an exemplary embodiment, the processor 202 may be configured to control the mixing operations performed by the mixer 410. The processor 202 may control and/or adjust the mixer 410 based on one or more signals received by the PSM 102, such as control signals received by the PSM transmitter 102. The control signals may be received via the I/O interface 208 (e.g. from one or more components of the audio system, one or more user devices, inputs from a sound engineer, etc.) and/or via the transceiver 206, which may include control signals from the PSM receiver 104 (and/or another component of the audio system), user device, or the like. For example, the performer associated with the PSM receiver 104 may adjust audio levels, EQ, and/or other parameters via the I/O interface 218, and these requested adjustments may be provided to the PSM transmitter 102. This allows for the performer to further customize their monitor mix to suit their individual preferences and needs.

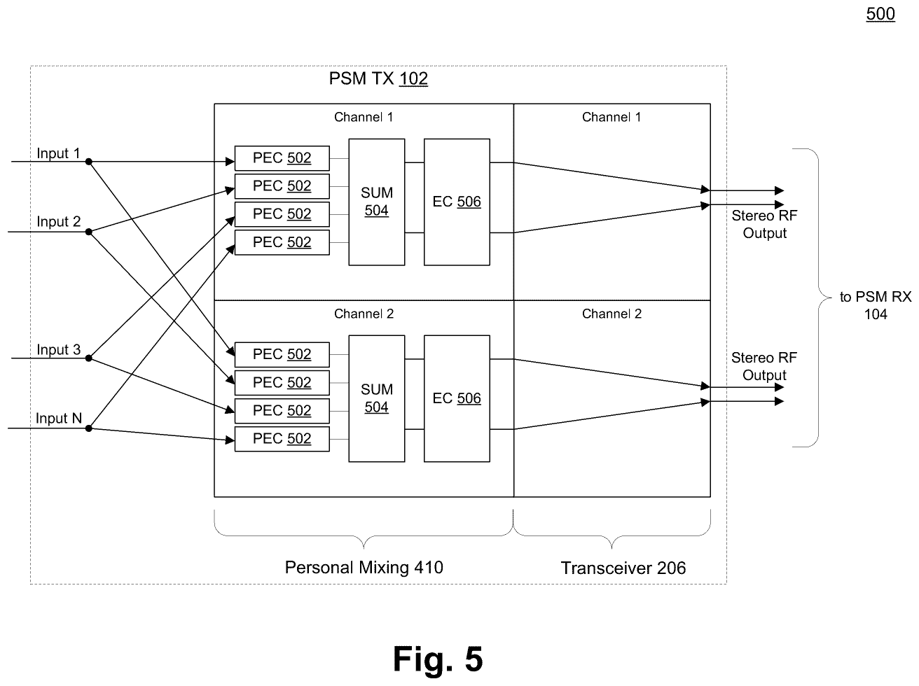

FIG. 5 illustrates an example operation 500 of audio system 400 according to one or more exemplary embodiments. The PSM transmitter 102 may receive one or more inputs on one or more channels. In the illustrated example, the PSM transmitter 102 is configured to accept inputs on two channels, but is not limited thereto. The first and/or second channels may be configured to receive a surround audio signal that includes four audio input signals. In other aspects, the inputs of the channels may include less or more audio input signals. In an exemplary embodiment, the input signals are received by the PSM transmitter 102 via the I/O interface 208.

The audio input signals may be processed by the mixer 410. In the illustrated example, the mixer 410 may perform a combination of equalization (EQ), panning, compression, and summing on the input audio signals. Additionally, or alternatively, the mixer 410 may perform one or more other mixing operations. In an exemplary embodiment, the mixer 410 may include a mixing/processing pipeline that includes two or more mixing stages. The individual mixing stages may include one or more mixing operations, which may be performed sequentially or at least partially simultaneously. In an exemplary embodiment, the mixing/processing pipeline may include three mixing stages. The first mixing stage may include panning, equalizing, and/or compression of the respective audio input signals, which generates a first intermediate mixed signal for the respective audio input streams. The first mixing stage may be performed by a panning, equalizing, and compressing (PEC) processor 502 of the mixer 410. In an exemplary embodiment, the mixer 410 may include respective PEC processors 502 for each of the audio input signals, but is not limited thereto. The resulting four intermediate signals may then be provided to the second mixing stage, which may be configured to sum the four intermediate signals to generate intermediate stereo signals. The summing operation may be performed by a summing processor 504 of the mixer 410. The intermediate stereo signal may then be provided to the third mixing stage that includes equalizing and/or compressing of the intermediate stereo signals to generate a mixed stereo output signal. The equalization and/or compression of the intermediate stereo signals may be performed by an equalizing and compression processor 506 of the mixer 410.

On the first and/or second channels, the mixed stereo output signals may be modulated to generate respective stereo RF output signals. For example, the transceiver 206 may modulate the stereo audio input signals onto a carrier wave to generate the RF output signals. The transceiver 206 may then transmit the RF output signals to the PSM receiver 104. Similar to the operation illustrated in FIG. 3, the PSM receiver 104 may receive the RF output signals from the PSM transmitter 102.

FIG. 6 illustrates an audio system 600 according to one or more exemplary embodiments. The audio system 600 may include PSM transmitter 102, PSM receiver 104, and one or more user devices 601. The user device 601 may be configured to externally controller the PSM transmitter 102, including controlling one or more components of the PSM transmitter 102. In an exemplary embodiment, the user device 601 is configured to control the mixer 410 of the PSM transmitter 102.

Although not illustrated, the user device 601 may be configured to additionally or alternatively communicate with the PSM receiver 104. This may include controlling the PSM transmitter 102 based on data received by the user device 601 from the PSM receiver 104 (including one or more components therein). The user device 601 may additionally or alternatively control one or more components of the PSM receiver 104 based on information received (e.g. status information, feedback from the performer, etc.) from the PSM receiver 104, PSM transmitter 102, and/or one or more other components of the audio system.

The user device 601 may be a computing device (e.g., desktop computer, laptop computer), mobile computing device (e.g., smartphone, tablet), and/or any other type of device that may be used for one or more audio applications, which may communicate with the PSM transmitter 102 to control the mixing operations of the mixer 410. The user device 601 may directly communicate with/control (e.g., via Bluetooth, IEEE 802.11 protocol(s), etc.) the PSM transmitter 102 and/or PSM receiver 104. Additionally, or alternatively, the user device 601 may communicate with/control the PSM transmitter 102 and/or PSM receiver 104 via a server and/or one or more other devices of the audio system. The user device 601 may transmit and/or receive data to/from: the PSM transmitter 102 via the I/O interface 208 and/or transceiver 206, and/or the PSM receiver 104 via the I/O interface 218 and/or transceiver 216.

The user device 601 may include one or more applications that may be used for audio processing and/or control tasks (e.g., panning, equalizing, compressing, summing, device volume control, noise cancelation, etc.). In an exemplary embodiment, the user of the user device 601 may adjust mixing parameters of the mixer 410 to adjust the mixing operations performed by the mixer 410. The adjustment may be based on data or information received from the PSM transmitter 102, PSM receiver 104, and/or one or more other components of the audio system.

In another example, the user device 601 may provide a user interface that may be used to configure audio processing of the PSM transmitter 102 (and/or PSM receiver 104). For example, the user interface may be used to input/control the configuration parameters, which may be provided to the PSM transmitter 102. The application may display, via the user device 601, a current status of the PSM transmitter 102 (and/or PSM receiver 104).

The user device 601 may be operated, for example, by the performer associated with the PSM receiver 104, a sound engineer at the sound booth/board, or one or more other persons/operators. For example, the performer can adjust mixing parameters (e.g. audio levels, EQ, and other parameters) of the mixer 410 using one or more applications on the user device 601. This allows for the performer to create a monitor mix that is tailored to their individual needs. The result is a high-quality, personalized monitoring experience that allows the performer to deliver their best possible performance on stage. In another example, the sound engineer may use a user device 601 to control operation of the mixer 410.

The user device 601 may present a user interface, such as graphical user interface (GUI), (e.g., via an installed application, or a web interface) that may be used to control operation of the mixer 410 and/or other component(s) of the PSM transmitter 102. The user associated with the user device 601 may access controls associated with the PSM transmitter 102, for example, by clicking/selecting an appropriate icon associated with the PSM transmitter 102 as illustrated in the GUI.

A user, associated with the user device 601, may authenticate themselves to enable control of the PSM transmitter 102 and/or other devices of the audio system. For example, the user may input, via the user interface on the user device 601, an account identifier and password associated with a user account.

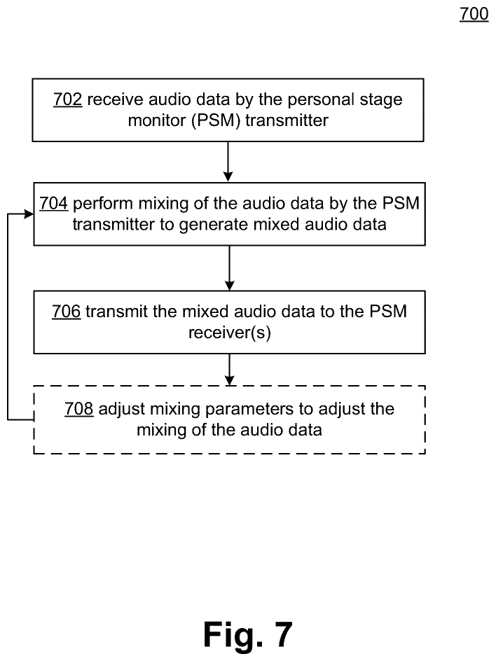

FIG. 7 shows an example method 700 of audio signal processing at a PSM transmitter according to one or more exemplary embodiments. Two or more of the various operations of the method 700 may be performed simultaneously in one or more aspects. Further, the order of the various operations is not limiting and the operations may be performed in a different order in one or more aspects.

At step 702, the PSM transmitter 102 may receive audio data. The data may be received from one or components of the audio system (e.g. microphones, receivers, mixers, amplifiers, speakers, musical instruments, general-purpose computing devices).

At step 704, the mixer 410 of the PSM transmitter 102 may perform mixing operations on the received audio data to generate mixed audio data. The mixing operations may include, for example, panning, equalization (EQ), compression, and/or summing. The mixing operations may include one or more other audio processing operations in other aspects. In an exemplary embodiment, the mixing operations include a multi-stage mixing process, where each stage includes performing one or more operations that may include, for example, panning, equalization (EQ), compression, and/or summing operations.

At step 706, the transceiver 206 of the PSM transmitter 102 may transmit the mixed audio data to the PSM receiver 104. In an exemplary embodiment, the transceiver 206 may be configured to transmit (and/or receive) signals to (and/or from) the PSM receiver 104 using one or more communication protocols.

At step 708, the adjustments to one or more mixing parameters may be made, and the adjusted parameters may be provided to the mixer 410 to adjust the mixing operations performed by the mixer 410. In an exemplary embodiment, the adjusted parameters may be provided to the mixer 410 using user device 601, a control panel in communication with the PSM transmitter 102 (e.g. a control panel located in the sound booth or at the soundboard), and/or adjustments made on a user interface of the PSM transmitter 102. Additionally, or alternatively, adjustments may be made by the performer using a user interface of the PSM receiver 104.

The techniques of this disclosure may also be described in the following clauses.

Clause 1. A personal stage monitor (PSM) device comprising: an audio processor configured to process one or more audio signals to generate one or more respective processed audio signals, the processing including mixing the one or more audio signals; and a transmitter configured to transmit the one or more processed audio signals to a receiver.

Clause 2. The PSM device of clause 1, wherein the audio processor is configured to perform panning, equalizing, and/or compression of the one or more audio signals to generate the one or more processed audio signals.

Clause 3. The PSM device of any of clauses 1-2, wherein the audio processor comprises a processing pipeline including: a first processing stage configured to perform panning, equalizing, and/or compression of the one or more audio signals, a second processing stage configured to perform summing on an output of the first processing stage, and a third processing stage configured to perform equalizing and/or compression on an output of the second processing stage to generate the one or more respective processed audio signals.

Clause 4. The PSM device of any of clauses 1-3, wherein the transmitter is configured to modulate the processed one or more audio signals to generate one or more modulated radio-frequency (RF) signals and transmit the one or more modulated RF signals to the receiver.

Clause 5. The PSM device of clause 4, wherein the transmitter is further configured to amplify and/or filter the one or more modulated RF signals and to transmit the amplified and/or filtered one or more modulated RF signals.

Clause 6. The PSM device of any of clauses 1-5, wherein the audio processor is configured to process the one or more audio signals on a plurality of channels, and the transmitter is configured to transmit the one or more processed signals on the plurality of channels.

Clause 7. The PSM device of any of clauses 1-6, wherein the audio processor is configured to process the one or more audio signals using one or more machine-learning (ML) algorithms.

Clause 8. A personal stage monitor (PSM) system comprising the PSM device of any of clauses 1-7.

Clause 9. The PSM system of clause 8, further comprising a PSM receiver configured to receive the one or more processed audio signals from the PSM device.

Clause 10. The PSM system of any of clauses 8-9, further comprising user device configured to: communicate with the PSM device, and control the audio processer and/or transmitter of the PSM device.

Clause 11. The PSM system of clause 10, wherein the user device comprises a user interface configured to receive an input from a user of the user device.

Clause 12. A personal stage monitor (PSM) system comprising: a PSM receiver; and a PSM transmitter configured to: process one or more audio signals to generate one or more respective processed audio signals, the processing including mixing the one or more audio signals; and transmit the one or more processed audio signals to the PSM receiver.

Clause 13. The PSM system of clause 12, wherein the PSM transmitter comprises an audio processor configured to process the one or more audio signals to generate the one or more respective processed audio signals, and a transmitter frontend configured to transmit the one or more processed audio signals to the PSM receiver.

Clause 14. The PSM system of clause 12, wherein the PSM transmitter comprises an audio mixer configured to mix the one or more audio signals to generate the one or more respective processed audio signals, and a transmitter frontend configured to transmit the one or more processed audio signals to the PSM receiver.

Clause 15. The PSM system of any of clauses 12-14, wherein the PSM transmitter is configured to perform panning, equalizing, and/or compression of the one or more audio signals to generate the one or more processed audio signals.

Clause 16. The PSM system of clause 13, wherein the audio processor comprises a processing pipeline including: a first processing stage configured to perform panning, equalizing, and/or compression of the one or more audio signals, a second processing stage configured to perform summing on an output of the first processing stage, and a third processing stage configured to perform equalizing and/or compression on an output of the second processing stage to generate the one or more respective processed audio signals.

Clause 17. The PSM system of clause 12, wherein the PSM transmitter is configured to modulate the processed one or more audio signals to generate one or more modulated radio-frequency (RF) signals and transmit the one or more modulated RF signals to the PSM receiver.

Clause 18. The PSM system of clause 17, wherein the PSM transmitter is further configured to amplify and/or filter the one or more modulated RF signals and to transmit the amplified and/or filtered one or more modulated RF signals to the PSM receiver.

Clause 19. The PSM system of any of clauses 12-18, wherein PSM transmitter is configured to process the one or more audio signals on a plurality of channels, and transmit the one or more processed signals on the plurality of channels.

Clause 20. The PSM system of any of clauses 12-19, further comprising a user device configured to: communicate with the PSM transmitter and/or the PSM receiver.

Clause 21. The PSM system of clause 20, wherein the user device is configured to control the processing of the one or more audio signals by the PSM transmitter.

Clause 22. The PSM system of any of clauses 20-21, wherein the user device comprises a user interface configured to receive an input from a user of the user device.

Clause 23. The PSM system of clause of any of clauses 12-22, wherein the PSM transmitter is configured to process the one or more audio signals using one or more machine-learning (ML) algorithms.

Clause 24. A method for monitoring an audio performance, comprising: receiving, by personal stage monitor (PSM) transmitter, audio data; mixing, by the PSM transmitter, the received audio data to generate mixed audio data; and transmitting, by the PSM transmitter, the mixed audio data to one or more PSM receivers.

Clause 25. The method of clause 24, wherein the audio data comprises a plurality of audio signals.

Clause 26. The method of any of clauses 24-25, wherein the mixing comprises panning, equalizing, and/or compressing the audio data to generate the mixed audio data.

Clause 27. The method of any of clauses 24-26, wherein the mixing comprises: a first mixing process including panning, equalizing, and/or compressing the audio data; a second mixing process including summing an output of the first mixing process; and a third mixing process including equalizing and/or compressing an output of the second mixing process to generate the mixed audio data.

Clause 28. The method of any of clauses 24-27, wherein transmitting the mixed audio data comprises modulating the mixed audio data to generate modulated radio-frequency (RF) data and transmitting the modulated RF data to the one or more PSM receivers.

Clause 29. The method of clause 28, wherein the transmitting further comprises amplifying and/or filtering the modulated RF data and transmitting the amplified and/or filtered modulated RF data to the one or more PSM receivers.

Clause 30. The method of any of clauses 24-29, wherein the audio data comprises a plurality of channels, the mixing of the audio data including respective mixing of the audio data on each of the plurality of channels to generate respective mixed audio data on each of the plurality of channels.

Clause 31. The method of clause 30, wherein the transmitting comprises transmitting the respective mixed audio data on the plurality of channels.

Clause 32. The method of clause of any of clauses 24-31, wherein mixing the received audio data uses one or more machine-learning (ML) algorithms.

Clause 33. A computer-readable medium storing instructions that, when executed, cause performance of the method any one of clauses 24-32.

Clause 34. A personal stage monitor (PSM) transmitter comprising one or more processors and memory storing instructions that, when executed by the one or more processors, cause the PSM transmitter to perform the method of any one of clauses 24-32.

Clause 35. A personal stage monitor (PSM) transmitter comprising: an audio mixer configured to mix one or more audio signals to generate one or more respective mixed audio signals; and a radio-frequency (RF) frontend configured to: modulate the one or more mixed audio signals to generate one or more modulated radio-frequency (RF) signals, and transmit the one or more modulated RF signals to a receiver.

Clause 36. The PSM transmitter of clause 35, wherein the audio mixer is configured to perform panning, equalizing, and/or compression of the one or more audio signals to generate the one or more mixed audio signals.

Clause 37. The PSM transmitter of any of clauses 35-36, wherein audio mixer comprises: a first mixer configured to perform panning, equalizing, and/or compression on the one or more audio signals, a second mixer configured to perform summing on an output of the first mixer, and a third mixer configured to perform equalizing and/or compression on an output of the second mixer to generate the one or more respective mixed audio signals.

Clause 38. The PSM transmitter of any of clauses 35-37, wherein the RF frontend is further configured to amplify and/or filter the one or more modulated RF signals and to transmit the amplified and/or filtered one or more modulated RF signals to the receiver.

Clause 39. The PSM transmitter of any of clauses 35-38, wherein the audio mixer is configured to mix the one or more audio signals on a plurality of channels, and the RF frontend is configured to transmit the one or more mixed audio signals on the plurality of channels.

Clause 40. The PSM transmitter of any of clauses 35-39, wherein the audio mixer is configured to mix the one or more audio signals using one or more machine-learning (ML) algorithms.

Clause 41. A personal stage monitor (PSM) system comprising the PSM transmitter of any of clauses 35-40.

Clause 42. The PSM system of clause 41, further comprising a PSM receiver configured to receive the one or more modulated RF signals from the PSM transmitter.

Clause 43. The PSM system of any of clauses 41-42, further comprising user device configured to: communicate with the PSM transmitter, and control the audio mixer and/or RF frontend of the PSM transmitter.

Clause 44. The PSM system of clause 43, wherein the user device is further configured to communicate with the PSM receiver.

Clause 45. The PSM system of any of clauses 43-44, wherein the user device comprises a user interface configured to receive an input from a user of the user device.

One or more aspects of the disclosure may be embodied in computer-usable data or computer-executable instructions, such as in one or more program modules, executed by one or more computers or other devices to perform the operations described herein. Generally, program modules include routines, programs, objects, components, data structures, and the like that perform particular tasks or implement particular abstract data types when executed by one or more processors in a computer or other data processing device. The computer-executable instructions may be stored as computer-readable instructions on a computer-readable medium such as a hard disk, optical disk, removable storage media, solid-state memory, RAM, and the like. The functionality of the program modules may be combined or distributed as desired in various embodiments. In addition, the functionality may be embodied in whole or in part in firmware or hardware equivalents, such as integrated circuits, application-specific integrated circuits (ASICs), field programmable gate arrays (FPGA), and the like. Particular data structures may be used to more effectively implement one or more aspects of the disclosure, and such data structures are contemplated to be within the scope of computer executable instructions and computer-usable data described herein.

Various aspects described herein may be embodied as a method, an apparatus, or as one or more computer-readable media storing computer-executable instructions. Accordingly, those aspects may take the form of an entirely hardware embodiment, an entirely software embodiment, an entirely firmware embodiment, or an embodiment combining software, hardware, and firmware aspects in any combination. In addition, various signals representing data or events as described herein may be transferred between a source and a destination in the form of light or electromagnetic waves traveling through signal-conducting media such as metal wires, optical fibers, or wireless transmission media (e.g., air or space). In general, the one or more computer-readable media may be and/or include one or more non-transitory computer-readable media.

As described herein, the various methods and acts may be operative across one or more computing servers and one or more networks. The functionality may be distributed in any manner, or may be located in a single computing device (e.g., a server, a client computer, and the like). For example, in alternative embodiments, one or more of the computing platforms discussed above may be combined into a single computing platform, and the various functions of each computing platform may be performed by the single computing platform. In such arrangements, any and/or all of the above-discussed communications between computing platforms may correspond to data being accessed, moved, modified, updated, and/or otherwise used by the single computing platform. Additionally, or alternatively, one or more of the computing platforms discussed above may be implemented in one or more virtual machines that are provided by one or more physical computing devices. In such arrangements, the various functions of each computing platform may be performed by the one or more virtual machines, and any and/or all of the above-discussed communications between computing platforms may correspond to data being accessed, moved, modified, updated, and/or otherwise used by the one or more virtual machines.

Aspects of the disclosure have been described in terms of illustrative embodiments thereof. Numerous other embodiments, modifications, and variations within the scope and spirit of the appended claims will occur to persons of ordinary skill in the art from a review of this disclosure. For example, one or more of the steps depicted in the illustrative figures may be performed in other than the recited order, and one or more depicted steps may be optional in accordance with aspects of the disclosure.

1. A personal stage monitor (PSM) device comprising:
an audio processor configured to process one or more audio signals to generate one or more respective processed audio signals, the processing including mixing the one or more audio signals; and
a transmitter configured to transmit the one or more processed audio signals to a receiver.

2. The PSM device of claim 1, wherein the audio processor is configured to perform panning, equalizing, and/or compression of the one or more audio signals to generate the one or more processed audio signals.

3. The PSM device of claim 1, wherein the audio processor comprises a processing pipeline including:
a first processing stage configured to perform panning, equalizing, and/or compression of the one or more audio signals;
a second processing stage configured to perform summing on an output of the first processing stage; and
a third processing stage configured to perform equalizing and/or compression on an output of the second processing stage to generate the one or more respective processed audio signals.

4. The PSM device of claim 1, wherein the transmitter is configured to modulate the processed one or more audio signals to generate one or more modulated radio-frequency (RF) signals and transmit the one or more modulated RF signals to the receiver.

5. The PSM device of claim 4, wherein the transmitter is further configured to amplify and/or filter the one or more modulated RF signals and to transmit the amplified and/or filtered one or more modulated RF signals.

6. The PSM device of claim 1, wherein the audio processor is configured to process the one or more audio signals on a plurality of channels, and the transmitter is configured to transmit the one or more processed signals on the plurality of channels.

7. The PSM device of claim 1, wherein the audio processor is configured to process the one or more audio signals using one or more machine-learning (ML) algorithms.

8. The PSM device of claim 1, wherein the receiver is a PSM receiver worn by a user.

9. A personal stage monitor (PSM) system comprising:
a PSM receiver; and
a PSM transmitter configured to:
process one or more audio signals to generate one or more respective processed audio signals, the processing including mixing the one or more audio signals; and
transmit the one or more processed audio signals to the PSM receiver.

10. The PSM system of claim 9, wherein the PSM transmitter comprises:
an audio processor configured to process the one or more audio signals to generate the one or more respective processed audio signals; and
a transmitter frontend configured to transmit the one or more processed audio signals to the PSM receiver.

11. The PSM system of claim 9, wherein the PSM transmitter comprises:
an audio mixer configured to mix the one or more audio signals to generate the one or more respective processed audio signals; and
a transmitter frontend configured to transmit the one or more processed audio signals to the PSM receiver.

12. The PSM system of claim 9, wherein the PSM transmitter is configured to perform panning, equalizing, and/or compression of the one or more audio signals to generate the one or more processed audio signals.

13. The PSM system of claim 9, wherein the audio processor comprises a processing pipeline including:
a first processing stage configured to perform panning, equalizing, and/or compression of the one or more audio signals;
a second processing stage configured to perform summing on an output of the first processing stage; and
a third processing stage configured to perform equalizing and/or compression on an output of the second processing stage to generate the one or more respective processed audio signals.

14. The PSM system of claim 9, wherein the PSM transmitter is configured to modulate the processed one or more audio signals to generate one or more modulated radio-frequency (RF) signals and transmit the one or more modulated RF signals to the PSM receiver.

15. The PSM system of claim 14, wherein the PSM transmitter is further configured to amplify and/or filter the one or more modulated RF signals and to transmit the amplified and/or filtered one or more modulated RF signals to the PSM receiver.

16. The PSM system of claim 9, wherein PSM transmitter is configured to process the one or more audio signals on a plurality of channels, and transmit the one or more processed signals on the plurality of channels.

17. The PSM system of claim 9, further comprising a user device configured to: communicate with the PSM transmitter and/or the PSM receiver.

18. The PSM system of claim 17, wherein the user device is configured to control the processing of the one or more audio signals by the PSM transmitter.

19. The PSM system of claim 17, wherein the user device is configured to control one or more operations of the PSM receiver.

20. The PSM system of claim 9, wherein the PSM transmitter is configured to process the one or more audio signals using one or more machine-learning (ML) algorithms.
